(19) United States
(12) Patent Application Publication
(10) Pub. No.: US 2026/0171363 A1
(43) Pub. Date: Jun. 18, 2026

(54) PLASMA PROCESSING APPARATUS AND PLASMA PROCESSING METHOD

(71) Applicant: Tokyo Electron Limited, Tokyo (JP)

(72) Inventors: Toshifumi KITAHARA, Tokyo (JP); Masaki HIRAYAMA, Tokyo (JP)

(21) Appl. No.: 19/437,827

(22) Filed: Dec. 31, 2025

Related U.S. Application Data
(63) Continuation of application No. PCT/JP2024/023321, filed on Jun. 27, 2024.

(30) Foreign Application Priority Data
Jul. 11, 2023 (JP) 2023-113519

(51) Int. Cl. H01J 37/32

(52) U.S. Cl. CPC H01J 37/32229

(57) ABSTRACT

A plasma processing apparatus includes: a processing container configured to provide a processing space; an emitter configured to emit electromagnetic waves to the processing space; and a waveguide configured to supply the electromagnetic waves to the emitter, wherein the waveguide includes an upstream waveguide constituting a portion of the waveguide and a downstream waveguide constituting another portion of the waveguide, the downstream waveguide being connected to the upstream waveguide via an elastic member, and wherein a gap length of a gap between the upstream waveguide and the downstream waveguide is adjustable by a pressing force between the upstream waveguide and the downstream waveguide.

### CROSS-REFERENCE TO RELATED APPLICATION

The application is a Bypass Continuation Application of PCT International Application No. PCT/JP2024/023321, filed on Jun. 27, 2024 and designating the United States, the international application being based upon and claiming the benefit of priority from Japanese Patent Application No. 2023-113519, filed on Jul. 11, 2023, the entire contents of which are incorporated herein by reference.

### TECHNICAL FIELD

The present disclosure relates to a plasma processing apparatus and a plasma processing method.

### BACKGROUND

A plasma processing apparatus disclosed in Patent Document 1 includes a processing container, a stage, an upper electrode, an introducer, and a waveguider. The stage is provided inside the processing container. The upper electrode is provided above the stage via a space inside the processing container. The introducer is an introducer of radio frequency waves. The radio frequency waves are very high frequency (VHF) waves or ultra-high frequency (UHF) waves. The introducer is provided in a lateral end portion of the space and extends in a circumferential direction around a central axis of the processing container. The waveguider is configured to supply the radio frequency waves to the introducer. The waveguider includes a resonator that provides a waveguide. The waveguide of the resonator extends in a circumferential direction around the central axis and in a direction in which the central axis extends, and is connected to the introducer.

### PRIOR ART DOCUMENT

### Patent Document

Patent Document 1: Japanese Patent Laid-open Publication No. 2020-092031

### SUMMARY

A processing apparatus according to the present disclosure includes: a processing container configured to provide a processing space; an emitter configured to emit electromagnetic waves to the processing space; and a waveguide configured to supply the electromagnetic waves to the emitter, wherein the waveguide includes an upstream waveguide constituting a portion of the waveguide and a downstream waveguide constituting another portion of the waveguide, the downstream waveguide being connected to the upstream waveguide via an elastic member, and wherein a gap length of a gap between the upstream waveguide and the downstream waveguide is adjustable by a pressing force between the upstream waveguide and the downstream waveguide.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a schematic perspective view illustrating an example of a plasma processing apparatus according to a first embodiment of the present disclosure.

FIG. 2 is a cross-sectional view illustrating an example of a cross-section taken along line A-A in FIG. 1.

FIG. 3 is a cross-sectional view illustrating an example of a cross-section taken along line B-B in FIG. 1.

FIG. 4 is a cross-sectional view illustrating an example of a cross-section taken along line C-C in FIG. 1.

FIG. 5 is an enlarged cross-sectional view illustrating an example of a vicinity of a contact surface between an upstream waveguide and a downstream waveguide.

FIG. 6 is a flowchart illustrating an example of plasma processing according to the first embodiment.

FIG. 7 is a schematic cross-sectional view illustrating an example of a plasma processing apparatus according to a second embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of a plasma processing apparatus and a plasma processing method according to the present disclosure will be described in detail with reference to the drawings. However, technology of the present disclosure is not limited to the following embodiments.

As in the plasma processing apparatus described above, in a case where an introducer configured to introduce radio frequency waves, which is very high frequency (VHF) waves or ultra-high frequency (UHF) waves, extends in a circumferential direction at a lateral end portion of a space inside a processing container, a waveguide of a resonator is fixed to an upper electrode. Further, the upper electrode is provided above a stage, that is, at an upper portion of the processing container. The waveguide of the resonator and the upper electrode are fixed by, for example, screws without a gap therebetween. Therefore, in order to adjust a distribution of plasma in the circumferential direction, a gap between the waveguide and the upper electrode needs to be adjusted by adjusting the screws according to a state of film formation. However, when the screws for fixing the waveguide are manually adjusted, a result of the adjustment cannot be identified unless film formation is actually performed. Therefore, the distribution of plasma in the circumferential direction is expected to be controlled by adjusting the gap between the waveguide and the upper electrode or between divided waveguides, even during plasma processing.

### First Embodiment

### [Configuration of Plasma Processing Apparatus 1]

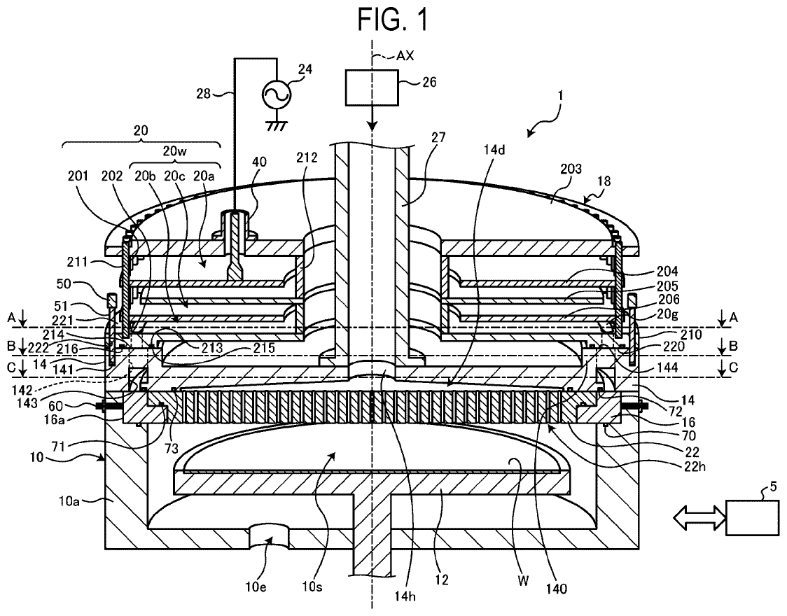

FIG. 1 is a schematic perspective view illustrating an example of a plasma processing apparatus according to a first embodiment of the present disclosure. A plasma processing apparatus 1 illustrated in FIG. 1 includes a controller 5, a chamber 10, a substrate support 12, an upper electrode 14, an emitter 16, and a waveguider 18.

A processing space 10s is provided inside the chamber 10. The processing space 10s includes a plasma generation space. The chamber 10 is an example of a processing container. In the plasma processing apparatus 1, a substrate W is processed inside the processing space 10s. The chamber 10 is made of a metal such as aluminum and is grounded. The chamber 10 includes a sidewall 10a and has an opening at an upper end thereof. The chamber 10 and the sidewall 10a may have a substantially cylindrical shape. The processing space 10s is provided inside the sidewall 10a. A central axis of each of the chamber 10, the sidewall 10a, and the processing space 10s is an axis AX. The chamber 10 may have a corrosion-resistant film on a surface thereof. The corrosion-resistant film may be an yttrium oxide film, an yttrium oxide fluoride film, an yttrium fluoride film, or a ceramic film including yttrium oxide, yttrium fluoride, or the like.

A bottom of the chamber 10 is provided with an exhaust port 10e. An exhauster is connected to the exhaust port 10e. The exhauster may include a vacuum pump, such as a dry pump and/or a turbomolecular pump, and an automatic pressure control valve.

The substrate support 12 is provided in the processing space 10s. The substrate support 12 is configured to substantially horizontally support the substrate W placed on an upper surface thereof. The substrate support 12 has a substantially disk-like shape. A central axis of the substrate support 12 is the axis AX.

The upper electrode 14 is provided above the substrate support 12 via the processing space 10s between the upper electrode 14 and the substrate support 12. The upper electrode 14 is made of a conductor such as a metal (e.g., aluminum) and has a substantially disk-like shape. A central axis of the upper electrode 14 is the axis AX.

The emitter 16 is provided to emit electromagnetic waves from the emitter 16 into the processing space 10s. In the plasma processing apparatus 1, the electromagnetic waves emitted from the emitter 16 into the processing space 10s excite a gas existing in the processing space 10s to generate plasma. The electromagnetic waves emitted from the emitter 16 into the processing space 10s may be radio frequency waves such as VHF waves or UHF waves. The emitter 16 is made of a dielectric material such as quartz, aluminum nitride, or aluminum oxide. The emitter 16 is provided in a lateral end portion of the processing space 10s and extends in a circumferential direction around the axis AX. The emitter 16 may have an annular shape. In addition, a plurality of electric field probes 60 (to be described later) for detecting electric field strength is provided on an outer side surface 16a of the emitter 16. Further, airtightness is maintained by O-rings 70 to 72 between the emitter 16 and the sidewall 10a, between the emitter 16 and a shower plate 22 to be described later, and between the emitter 16 and the upper electrode 14, respectively.

The waveguider 18 is configured to supply the electromagnetic waves to the emitter 16. The electromagnetic waves are generated by a radio-frequency power supply 24 to be described later. The electromagnetic waves propagate to the emitter 16 via the waveguider 18 and are introduced into the processing space 10s from the emitter 16. The waveguider 18 includes a resonator 20. Details of the resonator 20 will be described later. The waveguider 18 is an example of a waveguide and may include a waveguide provided inside the upper electrode 14.

In one embodiment, the plasma processing apparatus 1 may further include the shower plate 22. The shower plate 22 may be made of a metal such as aluminum. The emitter 16 extends along the shower plate 22 so as to surround the shower plate 22. The emitter 16 and the shower plate 22 are disposed to close the opening at the upper end of the chamber 10. The shower plate 22 provides a plurality of gas holes 22h. The plurality of gas holes 22h extends in a thickness direction (a vertical direction) of the shower plate 22 and penetrates the shower plate 22.

The shower plate 22 is provided below the upper electrode 14. The shower plate 22 and the upper electrode 14 define a gas diffusion space 14d therebetween. A central axis of the gas diffusion space 14d may be the axis AX. The plurality of gas holes 22h of the shower plate 22 is connected to the gas diffusion space 14d. In addition, the upper electrode 14 provides an inlet 14h. The inlet 14h may extend along the axis AX, for example, as shown in a gas supply pipe 27. The inlet 14h is connected to the gas diffusion space 14d. A gas supply 26 is connected to the gas diffusion space 14d. A gas output from the gas supply 26 is supplied to the processing space 10s via the gas supply pipe 27, the inlet 14h, the gas diffusion space 14d, and the plurality of gas holes 22h. In addition, an outside of the gas diffusion space 14d between the shower plate 22 and the upper electrode 14 is kept airtight by an O-ring 73. Further, the plasma processing apparatus 1 may be configured such that plasma generated in a plasma generation chamber (a remote plasma chamber), which is not shown, is supplied to the processing space 10s via the gas supply pipe 27, the inlet 14h, the gas diffusion space 14d, and the plurality of gas holes 22h.

The plasma processing apparatus 1 may further include the radio-frequency power supply 24. The radio-frequency power supply 24 is electrically coupled to the waveguide of the resonator 20 and is configured to generate radio frequency power having a variable frequency. The electromagnetic waves introduced into the chamber 10 are generated based on the radio frequency power generated by the radio-frequency power supply 24. The radio-frequency power supply 24 may be directly connected to the waveguide of the resonator 20 by using a coaxial line 28. That is, the radio-frequency power supply 24 may be coupled to the waveguide of the resonator 20 without passing through a matcher for impedance matching.

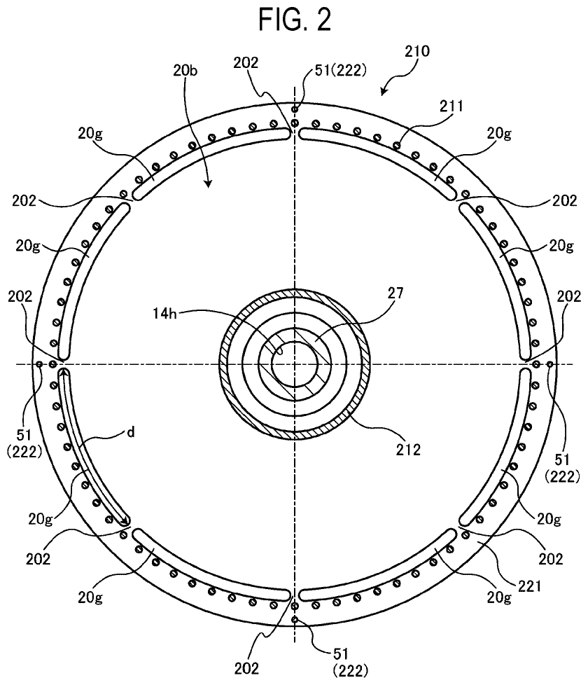

Hereinafter, reference will be made to FIGS. 2 to 5 together with FIG. 1. FIG. 2 is a cross-sectional view illustrating an example of a cross-section taken along line A-A in FIG. 1. The resonator 20 provides a waveguide 20w. The waveguide 20w may provide a cavity surrounded by a wall made of a conductor such as a metal (hereinafter referred to as a “conductor wall”). The conductor wall of the waveguide 20w may be made of aluminum alloy, copper, nickel, stainless steel, or the like, or may be coated with a low-resistance material such as silver, gold, or rhodium. As shown in FIG. 2, a portion of the conductor wall on an outer circumferential side of the resonator 20 may be constituted by a plurality of columns 211 arranged on a circumference. A spacing between the plurality of columns 211 is set based on a wavelength of the electromagnetic waves supplied from the radio-frequency power supply 24. That is, when the spacing between the plurality of columns 211 is sufficiently narrower than the wavelength of the electromagnetic waves, the plurality of columns 211 can be considered as a wall. The outer circumferential side of the resonator 20 may also be configured as a wall instead of the plurality of columns.

The resonator 20 includes a first short-circuit 201 and a plurality of second short-circuits 202. The first short-circuit 201 constitutes one end of the waveguide 20w of the resonator 20. In one embodiment, the first short-circuit 201 may extend along the circumferential direction around the axis AX. The plurality of second short-circuits 202 constitutes the other end of the waveguide 20w of the resonator 20.

In the resonator 20, an upper conductor wall 203 and a lower conductor wall 210 are connected at the outer circumferential side of the resonator 20 by the plurality of columns 211 and at an inner circumferential side of the resonator 20 by a wall 212. The wall 212 is an example of a conductor of the resonator 20 on a side of a central axis of the chamber 10. Alternatively, the inner circumferential side of the resonator 20 may be configured by columns instead of the wall 212, like the outer circumferential side. In addition, disk-shaped plates 204 to 206 are disposed between the upper conductor wall 203 and the lower conductor wall 210. The plate 205 is connected to the wall 212. On the other hand, the plate 205 is not connected to the plurality of columns 211, and a space between an end portion of the plate 205 on an outer circumferential side and the plurality of columns 211 constitutes a part of the waveguide 20w. The plates 204 and 206 are connected to the plurality of columns 211. On the other hand, the plates 204 and 206 are not connected to the wall 212, and spaces between end portions of the plates 204 on an inner circumferential side and 206 and the wall 212 constitute a part of the waveguide 20w. In other words, the plates 204 to 206 are disposed such that disks connected to the plurality of columns 211 and a disk connected to the wall 212 are disposed alternately to form the waveguide 20w as a labyrinth. That is, the waveguide 20w may have a layered structure including an upper portion 20a, a lower portion 20b, and an intermediate portion 20c.

As shown in FIG. 2, the lower conductor wall 210 includes a plurality of slots 20g in a vicinity of an inner periphery of the plurality of columns 211, which is formed on a circumference on an outer circumferential side of the lower conductor wall 210. The plurality of slots 20g penetrates the lower conductor wall 210 in a thickness direction (vertical direction) of the lower conductor wall 210 and is elongated in the circumferential direction. The plurality of slots 20g is spaced apart from one another and arranged in the circumferential direction around the axis AX. The plurality of slots 20g may be arranged at equal intervals. Spaces among the plurality of slots 20g serve as the second short-circuits 202, respectively. The second short-circuits 202 are alternately arranged with the plurality of slots 20g in the circumferential direction around the axis AX. The plurality of slots 20g is electromagnetically coupled to the emitter 16 via a plurality of slots 142 and an annular waveguide 143. The plurality of second short-circuits 202 connect an inner portion and an outer portion of the lower conductor wall 210 to each other.

A distance in the circumferential direction between any two second short-circuits 202 adjacent in the circumferential direction among the plurality of second short-circuits 202 may satisfy the following Equation (1).

$$0.05 λ g < d < 0.2 λ g \qquad ( 1 )$$

Here, λ_{g} is the wavelength of the electromagnetic waves in the waveguide 20w. When Equation (1) is satisfied, the resonator 20 can supply a portion of the electromagnetic waves propagating through the waveguide 20w to the emitter 16 and can have an appropriately large reflection coefficient of the electromagnetic waves at the other end of the waveguide 20w of the resonator 20.

A resonator length L of the resonator 20 between the first short-circuit 201 and the plurality of second short-circuits 202 (a distance connecting the first short-circuit 201 and the plurality of second short-circuits 202 along the waveguide 20w) may satisfy the following Equation (2).

$$( n - 0.2 ) λ g / 2 < L < n λ g / 2 \qquad ( 2 )$$

As described above, λ_{g} is the wavelength of the electromagnetic waves in the waveguide 20w, and n is an integer equal to or greater than 1. A reactance of the plurality of slots 20g is inductive. Accordingly, in order to satisfy Equation (2), the resonator length L may be set to a value slightly smaller than nλ_{g}/2.

In the plasma processing apparatus 1, resonance of the electromagnetic waves is generated between the first short-circuit 201 and the plurality of second short-circuits 202. The electromagnetic waves resonating in the resonator 20 is supplied to the plurality of slots 142 formed in a connection portion 140 of the upper electrode 14 via the plurality of slots 20g.

In one embodiment, the plasma processing apparatus 1 may further include a connector 40 for introducing the electromagnetic waves into the waveguide 20w. The connector 40 is a portion of the coaxial line 28. The radio-frequency power supply 24 is coupled to the upper portion 20a via the coaxial line 28 and the connector 40. The connector 40 may be coupled to the upper portion 20a at a position spaced apart from the axis AX in a radial direction. The connector 40 may be, for example, a coaxial connector. A length (height) of the upper portion 20a in a direction along which the axis AX extends may be greater than lengths of other portions (the lower portion 20b and the intermediate portion 20c) of the waveguide 20w in the vertical direction.

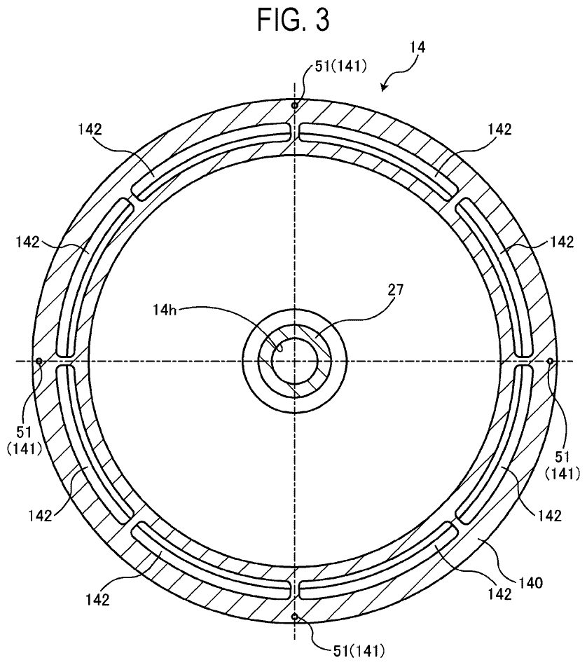

FIG. 3 is a cross-sectional view illustrating an example of a cross-section taken along line B-B in FIG. 1. The plurality of slots 142 of the upper electrode 14 are formed correspondingly to the plurality of slots 20g of the lower conductor wall 210 of the resonator 20, respectively. In addition, the plurality of slots 142 is formed to penetrate the annular connection portion 140 in an outer peripheral portion of the upper electrode 14 in the direction along which the axis AX extends. An upper surface 144 of the connection portion 140 faces a lower surface 220 of the lower conductor wall 210.

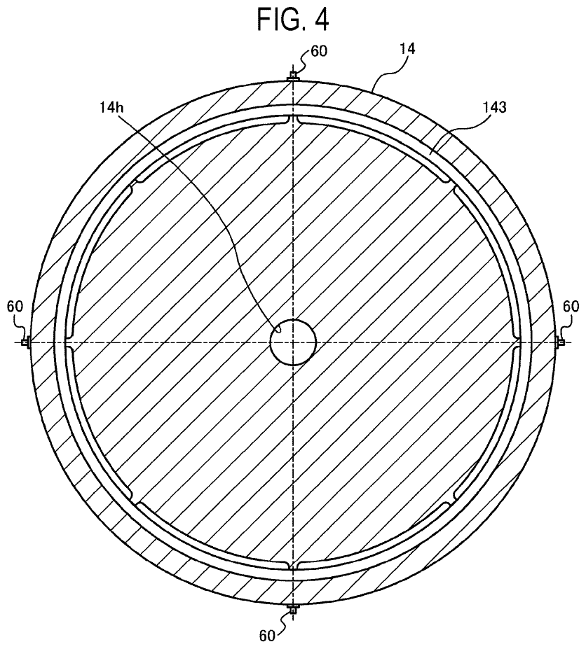

FIG. 4 is a cross-sectional view illustrating an example of a cross-section taken along line C-C in FIG. 1. As shown in FIG. 4, the annular waveguide 143 is formed below the plurality of slots 142. The annular waveguide 143 is an example of an annular space. That is, the waveguide 143 is connected to each of the plurality of slots 142 and is formed, together with the plurality of slots 142, to penetrate the connection portion 140 in the direction along which the axis AX extends. As shown in FIG. 1, a lower portion of the waveguide 143 is in contact with an upper surface of the emitter 16. In other words, the electromagnetic waves, which have propagated through the plurality of slots 142 and the waveguide 143, are supplied to the emitter 16.

In the following description, a portion from the connector 40 of the resonator 20 to a connection surface between the plurality of slots 20g and the plurality of slots 142 (i.e., a connection surface between the upper surface 144 and the lower surface 220) may be referred to as an upstream waveguide UW, and a portion from the connection surface to the emitter 16 may be referred to as a downstream waveguide DW. That is, the waveguider 18 includes the upstream waveguide UW and the downstream waveguide DW. For example, it can be said that the plurality of slots 20g extending in the circumferential direction of the chamber 10 is formed at a connection portion (i.e., the lower surface 220 of the lower conductor wall 210) of the resonator 20 and the downstream waveguide DW.

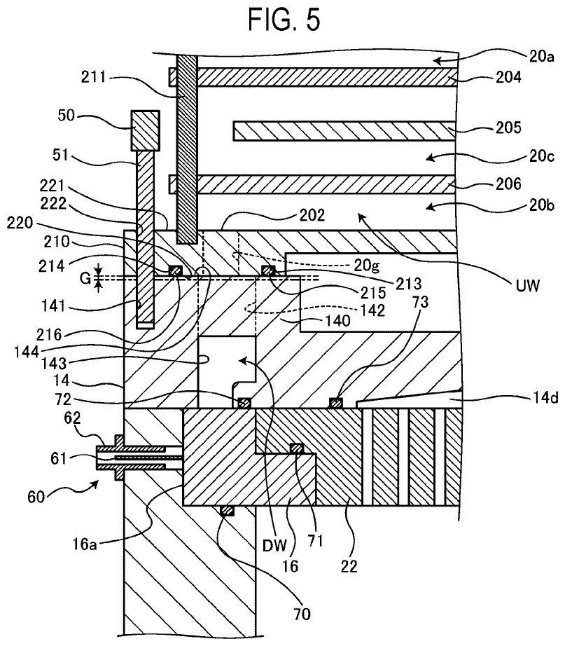

FIG. 5 is an enlarged cross-sectional view illustrating an example of a vicinity of a connection surface between an upstream waveguide and a downstream waveguide. As shown in FIG. 5, the upstream waveguide UW and the downstream waveguide DW are connected with each other at the connection surface between the upper surface 144 and the lower surface 220.

Annular grooves 213 and 214 are formed in the lower surface 220. The groove 213 is formed on an inner circumferential side than the plurality of slots 20g, and the groove 214 is formed on an outer circumferential side than the plurality of slots 20g. Elastic members 215 and 216 are inserted into the grooves 213 and 214, respectively. The elastic members 215 and 216 are, for example, obliquely-wound coil springs. A gap G between the upper surface 144 and the lower surface 220 is adjusted by controlling actuators 50 and rods 51, and when a space is formed between the upstream waveguide UW and the downstream waveguide DW, the space is electromagnetically shielded by the elastic members 215 and 216. FIG. 5 shows a state in which the upper surface 144 and the lower surface 220 are in contact with each other, and indicates a gap length of the gap G when the space is formed by dash-double-dotted lines.

As shown in FIGS. 2 and 3, for example, four actuators 50 and four rods 51 are provided at 12 o'clock, 3 o'clock, 6 o'clock, and 9 o'clock positions, respectively, in the circumferential direction of the chamber 10 in a plan view. The actuators 50 and rods 51 may be disposed at equal intervals along the circumferential direction of the chamber 10. Each actuator 50 is individually controlled by the controller 5. Each of the number of actuators 50 and the number of rods 51 is not limited to four, and, for example, two or more actuators 50 and rods 51 may be provided in the circumferential direction of the chamber 10. Specifically, each of the number of actuators 50 and the number of rods 51 may fall within a range of, for example, three to six.

The rods 51 are inserted into through-holes 222, which penetrate from an upper surface 221 to the lower surface 220 of the lower conductor wall 210, and holes 141 formed in the upper surface 144 of the connection portion 140. The actuators 50 can adjust the gap length of the gap G by moving the rods 51 in the direction along which the axis AX extends. In other words, the actuators 50 adjust a pressing force acting on the connection surface between the upstream waveguide UW and the downstream waveguide DW. That is, the gap length of the gap G between the upstream waveguide UW and the downstream waveguide DW can be adjusted by the pressing force between the upstream waveguide UW and the downstream waveguide DW. The gap length of the gap G can be adjusted, for example, within a range of approximately 0 mm (contact state) to 1 mm, and as the gap length of the gap G decreases, an electric field detected by the electric field probes 60 at corresponding locations increases. That is, the controller 5 can control a distribution of plasma in the circumferential direction by adjusting the gap length of the gap G through controlling the actuators 50. The gap length of the gap G may be adjusted within a range of 0 mm to 0.6 mm with a reference value of, for example, 0.3 mm. The actuators 50 and the rods 51 may be configured to adjust the gap length of the gap G by using screws and ball screws. Further, since the lower conductor wall 210 only needs to be pressed toward the upper electrode 14, it is not essential to provide the through-holes 222 in the lower conductor wall 210. In such a case, the actuators 50 may be fixed to a frame or the like which is not shown.

The electric field probes 60 are an example of an electric field sensor and is, for example, coaxial-shaped probes. As shown in FIGS. 1 to 5, in a plan view of the chamber 10, the plurality of electric field probes 60 are provided, for example, on extension lines connecting the actuators 50 and rods 51 to the axis AX (a center of the chamber 10.) For example, in the plan view of the chamber 10, four electric field probes 60 are provided in the circumferential direction of the chamber 10 at 12 o'clock, 3 o'clock, 6 o'clock, and 9 o'clock positions. When the plurality of electric field probes 60 are provided, the electric field probes 60 have the same position (height) in the direction along which the axis AX extends. The number of electric field probes 60 may be one or more, and is not particularly limited.

An end portion of each electric field probe 60 facing outward has a shape of a coaxial connector, and includes an inner conductor 61 and an outer conductor 62. The inner conductor 61 is provided to extend to a vicinity of the side surface 16a of the emitter 16, and is slightly spaced apart from the side surface 16a. Therefore, influence of providing the electric field probe 60 on the distribution of plasma can be minimized. The inner conductor 61 may be in contact with the side surface 16a or extend into the dielectric inside the emitter 16. The outer conductor 62 is electrically connected to the sidewall 10a of the chamber 10. Information on the electric field (e.g., electric field strength) detected by the electric field probes 60 is input to the controller 5.

The controller 5 processes computer-executable instructions that cause the plasma processing apparatus 1 to execute various processes such as film formation and etching. The controller 5 may be configured to control individual components of the plasma processing apparatus 1 to execute various processes. In one embodiment, a part or entirety of the controller 5 may be included in the plasma processing apparatus 1. The controller 5 may include a processor, a storage, and a communication interface. The controller 5 is implemented by, for example, a computer. The processor may be configured to perform various control operations by reading a program from the storage and executing the read program. The program may be stored in the storage in advance or may be acquired via a medium when necessary. The acquired program is stored in the storage, and is read from the storage and executed by the processor. The storage stores, for example, a process recipe, which is a process sequence and control parameters of the plasma processing apparatus 1. The medium may be various non-transitory storage media readable by the computer or may be a communication line connected to the communication interface. The processor may be a central processing unit (CPU). The storage may include a random access memory (RAM), a read only memory (ROM), a hard disk drive (HDD), a solid state drive (SSD), or a combination thereof. The communication interface may communicate with the plasma processing apparatus 1 via a communication line such as a local area network (LAN).

The controller 5 can perform predetermined control according to a selected process recipe. For example, the controller 5 controls individual components of the plasma processing apparatus 1 to execute a plasma processing method to be described later. In a specific example, the controller 5 executes a process of preparing the substrate W by loading the substrate W into the chamber 10. The controller 5 executes a process of generating plasma by supplying a process gas into the chamber 10 and plasma-processing the substrate W by using the generated plasma. Here, the plasma processing may be, for example, film formation process, an etching process, or another type of process. In addition, when the plasma processing is performed on the substrate W as a processing target in the processing space 10s inside the chamber 10, the controller 5 controls each actuator 50 to adjust the gap length of the gap G such that, for example, electric field strengths of the plurality of electric field probes 60 become equal to one another. That is, the controller 5 controls each actuator 50 such that the distribution of plasma in the circumferential direction is made uniform. Further, the controller 5 may control the plurality of actuators 50 such that the gap length of the gap G varies along the circumferential direction of the chamber 10.

### [Plasma Processing Method]

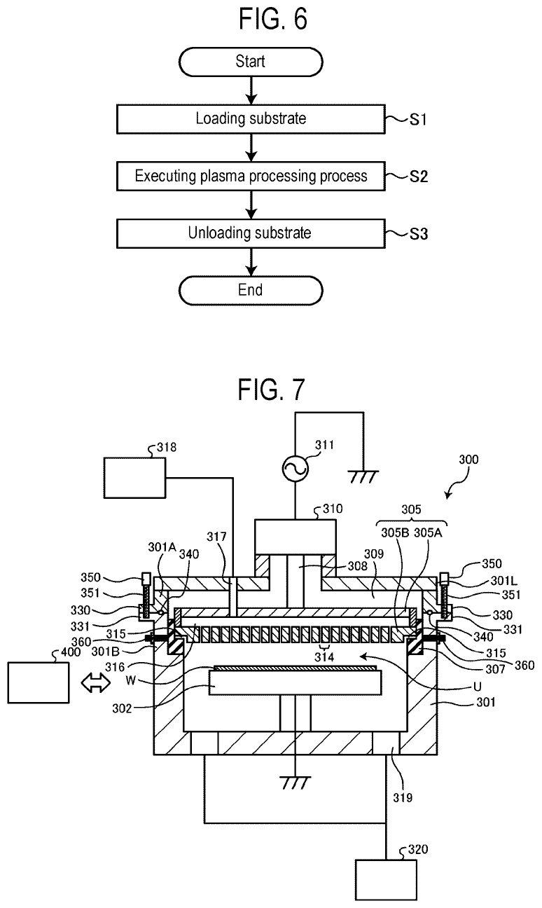

Next, plasma processing according to a first embodiment will be described as a plasma processing method. FIG. 6 is a flowchart illustrating an example of plasma processing according to the first embodiment.

The controller 5 controls a gate valve (not shown) to open a load/unload port (not shown). When the load/unload port is open, the substrate W is loaded into the processing space 10s of the chamber 10 via the load/unload port and is placed on the substrate support 12. That is, the controller 5 controls the plasma processing apparatus 1 so as to load the substrate W into the chamber 10 (Step S1). The controller 5 may also be a control device for an entire substrate processing system (not shown) including the plasma processing apparatus 1 and a transfer device of a transfer chamber (not shown) adjacent to the chamber 10. The controller 5 controls the gate valve to close the load/unload port. Step S1 is an example of a process of preparing the substrate W by loading the substrate W into the chamber 10.

The controller 5 controls an exhauster (not shown) connected to the exhaust port 10e to depressurize an interior of the chamber 10 to a predetermined pressure. The controller 5 controls the gas supply 26 to supply a plasma generation gas into the chamber 10 via the plurality of gas holes 22h. The controller 5 controls the radio-frequency power supply 24 to generate plasma at a predetermined power. The controller 5 executes a plasma processing process (Step S2) of plasma-processing the substrate W by using plasma of the plasma generation gas for a predetermined period of time.

In the plasma processing process, the controller 5 controls each actuator 50 to adjust the gap length of the gap G such that, for example, the electric field strengths of the plurality of electric field probes 60 become equal to one another when the substrate W is plasma-processed. That is, the controller 5 performs feedback control of the gap length based on the detected electric field. The controller 5 may continuously control each actuator 50 to adjust the gap length of the gap G such that an intensity distribution (electric field strength distribution) of plasma in the circumferential direction is rotated in the circumferential direction of the chamber 10.

When the plasma processing process is completed, the controller 5 stops the supply of the electromagnetic waves to terminate plasma generation. The controller 5 also controls the gate valve to open the load/unload port. The controller 5 controls the plasma processing apparatus 1 such that lift pins (not shown) protrude from an upper surface of the substrate support 12 to lift the substrate W. While the load/unload port is open, the substrate W is unloaded from the chamber 10 by an arm of the transfer chamber, which is not shown, via the load/unload port. That is, the controller 5 controls the plasma processing apparatus 1 to unload the substrate W from the chamber 10 (Step S3). As described above, the controller 5 can control the distribution of plasma in the circumferential direction by adjusting the gap length of the gap G, even during the plasma-processing.

### Second Embodiment

Although the electromagnetic waves are supplied by using the resonator 20 in the first embodiment described above, the plasma processing apparatus may also be configured to supply electromagnetic waves from above a center of the upper electrode 14. An embodiment of such a case will now be described as a second embodiment.

FIG. 7 is a schematic cross-sectional view illustrating an example of a plasma processing apparatus according to the second embodiment. A plasma processing apparatus 300 shown in FIG. 7 includes a chamber 301 having an opening at an upper portion thereof, a lid 301L that seals the upper opening of the chamber 301, a substrate support (stage) 302 disposed inside the chamber 301, and a plasma generation source located above the substrate support 302. The chamber 301 is an example of a processing container. The substrate support 302 is also referred to as a lower electrode or a stage.

The plasma generation source includes an upper electrode 305 disposed to face the substrate support 302 and an emitter 307 having an electromagnetic wave radiation port. The emitter 307 corresponds to the emitter 16 of the first embodiment. A plasma generation space U is formed between the upper electrode 305 and the substrate support 302 inside the chamber 301. The emitter 307 is made of a dielectric material such as alumina (Al₂O₃).

Electromagnetic waves are radiated from the emitter 307 to the plasma generation space U. The emitter 307 serves as an introducer of the electromagnetic waves, and a step portion having an annular upper surface is formed on an inner wall surface of the chamber 301. The emitter 307 is coupled to the step portion, and is disposed on and supported by the upper surface of the step portion. The emitter 307 is fit into the chamber 301 along an entire circumference of the chamber 301. That is, the electromagnetic waves are radiated downward over the entire circumference from the emitter 307 disposed along the circumferential direction of the chamber 301.

A substrate W is disposed on the substrate support 302. The substrate W is not particularly limited as long as plasma processing is performed on the substrate, and may be a semiconductor substrate, an insulating substrate such as glass or alumina, or a metal substrate.

A gas inside the chamber 301 may be exhausted to the outside by an exhauster 320 via an exhaust port 319. A process gas is supplied into the chamber 301 from a gas source 318 via a supply pipe 317. Specifically, the upper electrode 305 has a shower structure with a gas diffusion space 316 formed in an internal space of the upper electrode 305. The supply pipe 317 penetrates the lid 301L and is in communication with and connected to an inside of the gas diffusion space 316 via the waveguide 309. In this example, the upper electrode 305 has a metal shower plate structure, and includes the gas diffusion space 316 into which the process gas is introduced and a plurality of gas holes 314 via which the gas diffusion space 316 is in communication with an internal space of the chamber 301. The upper electrode 305 includes an upper metal member 305A having a recess on a lower surface thereof and a lower metal member 305B having the plurality of gas holes 314. The gas diffusion space 316 is formed at a position of the recess between the metal members 305A and 305B. The process gas introduced into the gas diffusion space 316 is supplied into the chamber 301 via the plurality of gas holes 314 provided in a lower region of the upper electrode 305. The upper electrode 305 is an example of an electrode to which electromagnetic waves for generating plasma are applied.

A waveguide 309 is formed along an outer periphery of the upper electrode 305 in a space defined by the upper electrode 305, a lower surface of the lid 301L, and an inner surface of the chamber 301. The chamber 301 includes an annular member 301A formed at the upper portion thereof and a chamber body 301B. The annular member 301A and the chamber body 301B are connected via an elastic member 340. In other words, the annular member 301A can be considered as a member obtained by dividing an upper portion of a sidewall of the chamber 301. The elastic member 340 is, for example, an obliquely-wound coil spring. An upper portion of the annular member 301A is in contact with the lower surface of the lid 301L. A flange 330 is formed in a lower portion of the annular member 301A. A flange 331 is formed in an opposing upper portion of the chamber body 301B. A plurality of actuators 350 and a plurality of rods 351, for example, are provided on the flanges 330 and 331, and a gap length of a gap between the flange 330 and the flange 331 can be adjusted. The gap between the flange 330 and the flange 331 corresponds to a gap between a lower surface of the annular member 301A and an upper surface of the chamber body 301B, and corresponds to the gap G of the first embodiment. That is, in the plasma processing apparatus 300 of the second embodiment, a waveguide length from the waveguide 309 to the emitter 307 can be adjusted. The gap between the flange 330 and the flange 331 is electromagnetically shielded by the elastic member 340. Since the actuators 350 and the rods 351 correspond to the actuators 50 and the rods 51 of the first embodiment and have the same functions, a detailed description thereof will be omitted.

In an upper outer portion of a sidewall of the chamber body 301B, electric field probes 360 are provided at positions corresponding to those of the actuators 350 in the circumferential direction in a plan view of the chamber 301, respectively. The electric field probes 360 can detect the electric field of the emitter 307. Information on the electric field (e.g., electric field strength) detected by the electric field probes 360 is output to a controller 400. The electric field probes 360 correspond to the electric field probes 60 of the first embodiment and perform the same functions.

In the plasma processing apparatus 300, power of electromagnetic waves is supplied to an upper portion of the upper electrode 305 from a power supply 311 via a first matcher 310 and a power transmission line 308. The supplied electromagnetic waves propagate radially in a horizontal direction through the waveguide 309. When the electromagnetic waves reach the inner surface of the chamber 301 (annular member 301A), the electromagnetic waves propagate downward into the emitter 307, and are emitted to the plasma generation space U from an inner tip surface of a protrusion in a lower portion of the emitter 307 and a multi-factor discharger 315. The electromagnetic waves propagate horizontally toward a central axis of the chamber 301. The electromagnetic waves may be in the VHF or UHF (microwave) band. In the second embodiment, a portion of the waveguide 309 from a center of the upper electrode 305 to a connection surface between the lower surface of the annular member 301A and the upper surface of the chamber body 301B is an example of an upstream waveguide UW, and a portion of the waveguide 309 from the connection surface to an upper surface of the emitter 307 is an example of a downstream waveguide DW.

In a state in which the process gas is introduced into the chamber 301 and the interior of the chamber 301 is depressurized by the exhauster 320 to a pressure at which plasma can be generated, when the electromagnetic waves are introduced into the chamber 301, plasma is generated in the plasma generation space U below the upper electrode 305. The plasma generation space U is positioned directly below the upper electrode 305. Further, one end of the power supply 311 is connected to the first matcher 310, and the other end of the power supply 311 is connected to the ground. The power transmission line 308 may be any line capable of transmitting electromagnetic waves in the VHF band or the like, and as an electromagnetic wave transmission component, a coaxial cable may be used in addition to a waveguide tube. Although the substrate support 302 is electrically connected to the ground in this example, radio-frequency waves or electromagnetic waves may be applied to the substrate support 302.

In the chamber 301, a central axis extending in the vertical direction is defined as a Z-axis, an axis perpendicular to the Z-axis is defined as an X-axis, and an axis perpendicular to both the Z-axis and the X-axis is defined as a Y-axis. In this case, an XY plane constitutes a horizontal plane. A central axis of the emitter 307 coincides with the central axis (the Z-axis) of the chamber 301 in the vertical direction.

The controller 400 processes computer-executable instructions that cause the plasma processing apparatus 300 to execute various processes such as film formation and etching. The controller 400 may be configured to control individual components of the plasma processing apparatus 300 to execute various processes. In one embodiment, a part or entirety of the controller 400 may be included in the plasma processing apparatus 300. The controller 400 may include a processor, a storage, and a communication interface. The controller 400 is implemented by, for example, a computer. The processor may be configured to perform various control operations by reading a program from the storage and executing the read program. The program may be stored in the storage in advance or may be acquired via a medium when necessary. The acquired program is stored in the storage, and is read from the storage and executed by the processor. The medium may be various non-transitory storage media readable by the computer or may be a communication line connected to the communication interface. The processor may be a CPU. The storage may include a RAM, a ROM, an HDD, an SSD, or a combination thereof. The communication interface may communicate with the plasma processing apparatus 300 via a communication line such as a LAN.

Thus, in the plasma processing apparatus 300 of the second embodiment as well, distribution of plasma in the circumferential direction can be controlled by adjusting the gap length between the flange 330 and the flange 331 during plasma processing by the controller 400.

As described above, according to each embodiment, a plasma processing apparatus (the plasma processing apparatus 1 or 300) includes a processing container (the chamber 10 or 301) providing a processing space (the processing space 10s or the plasma generation space U), an emitter (the emitter 16 or 307) configured to emit electromagnetic waves to the processing space, and a waveguide (the waveguider 18 or the waveguide 309) configured to supply the electromagnetic waves to the emitter. The waveguide includes an upstream waveguide UW which constitutes a portion of the waveguide, and a downstream waveguide DW, which constitutes another portion of the waveguide and is connected to the upstream waveguide UW via an elastic member (the elastic members 215 and 216, or the elastic member 340). A gap length of a gap between the upstream waveguide UW and the downstream waveguide DW can be adjusted by a pressing force therebetween. As a result, distribution of plasma in the circumferential direction can be controlled.

According to each embodiment, the elastic member is a coil spring. As a result, a connection surface between the upstream waveguide UW and the downstream waveguide DW can be shielded.

According to each embodiment, the plasma processing apparatus also includes a plurality of actuators (the actuators 50 or 350) that adjusts the pressing force at the connection surface between the upstream waveguide UW and the downstream waveguide DW. As a result, a waveguide length can be adjusted, and distribution of plasma in the circumferential direction can be controlled.

According to each embodiment, the plasma processing apparatus also includes an electric field sensor (the electric field probes 60 or 360) that detects an electric field at the emitter. The gap length is adjusted based on the detected electric field. As a result, distribution of plasma in the circumferential direction can be controlled based on the detected electric field.

According to each embodiment, the plasma processing apparatus also includes a controller (the controller 5 or 400). The controller may be configured to control the plasma processing apparatus such that, when a substrate (the substrate W) as a processing target is plasma-processed in the processing space, the plurality of actuators is controlled to vary the gap length along a circumferential direction of the processing container. As a result, distribution of plasma in the circumferential direction can be controlled to rotate, and in-plane uniformity of plasma can be further improved in at least one of a film forming process or an etching process.

According to the first embodiment, the upstream waveguide UW includes the resonator 20 capable of resonating with the electromagnetic waves. The resonator 20 is configured such that a disk (the plate 205) connected to a conductor (the wall 212) on a central axis side of the processing container and a disk (the plate 204 or 206) connected to a conductor (the plurality of columns 211) on an outer wall side of the processing container are alternately disposed. The plurality of slots 20g extending in the circumferential direction of the processing container is formed at a connection portion (the lower surface 220 of the lower conductor wall 210) of the resonator 20 and the downstream waveguide DW. As a result, the electromagnetic waves can be supplied to the emitter 16.

According to the first embodiment, the downstream waveguide DW includes an annular space (the waveguide 143). The plurality of slots 20g is connected to the annular space. As a result, the electromagnetic waves can be supplied to the emitter 16.

According to the first embodiment, the elastic members 215 and 216 are provided on an inner circumferential peripheral side and an outer circumferential peripheral side of the plurality of slots 20g, respectively. As a result, even when the gap G is adjusted and a space is formed between the upstream waveguide UW and the downstream waveguide DW, the space is electromagnetically shielded by the elastic members 215 and 216.

According to each embodiment, the plasma processing apparatus further includes a shower plate (the shower plate 22 or the lower metal member 305B) that supplies a process gas to the processing space. The emitter is formed of an annular dielectric and is provided to surround the shower plate. As a result, the electromagnetic waves can be supplied from an outer circumferential side toward a center of the chamber 10 or 301.

It should be noted that the embodiments disclosed herein are exemplary in all aspects and are not restrictive. The above-described embodiments may be omitted, replaced, or modified in various forms without departing from the scope and spirit of the appended claims.

In the above-described embodiments, while the plasma processing apparatuses 1 and 300 configured to supply the electromagnetic waves to the emitters 16 and 307 provided on the sidewalls of the chambers 10 and 301 have been described, the present disclosure is not limited thereto. For example, in a plasma processing apparatus that supplies the electromagnetic waves to an upper electrode from a radio-frequency power supply by using a waveguide, the waveguide may be divided into an upstream waveguide UW and a downstream waveguide DW, elastic members may be provided between the upstream waveguide UW and the downstream waveguide DW, and actuators and rods may also be provided.

The present disclosure may be configured as follows.
(1) A plasma processing apparatus, including:
a processing container configured to provide a processing space;
an emitter configured to emit electromagnetic waves to the processing space; and
a waveguide configured to supply the electromagnetic waves to the emitter,
wherein the waveguide includes an upstream waveguide constituting a portion of the waveguide and a downstream waveguide constituting another portion of the waveguide, the downstream waveguide being connected to the upstream waveguide via an elastic member, and
wherein a gap length of a gap between the upstream waveguide and the downstream waveguide is adjustable by a pressing force between the upstream waveguide and the downstream waveguide.
(2) The plasma processing apparatus of (1), wherein the elastic member is a coil spring.
(3) The plasma processing apparatus of (1) or (2), further including a plurality of actuators configured to adjust the pressing force at a contact surface between the upstream waveguide and the downstream waveguide.
(4) The plasma processing apparatus of (3), further including an electric field sensor provided in the emitter and configured to detect an electric field,
wherein the gap length is adjusted based on the detected electric field.
(5) The plasma processing apparatus of (4), further including a controller, wherein the controller is configured to control the plasma processing apparatus to execute controlling the plurality of actuators to vary the gap length along a circumferential direction of the processing container when a substrate as a processing target is plasma-processed in the processing space.
(6) The plasma processing apparatus of any one of (1) to (5), wherein the upstream waveguide includes a resonator resonating with the electromagnetic waves, and
wherein the resonator is configured such that a disk connected to a conductor on a central axis side of the processing container and a disk connected to a conductor on an outer wall side of the processing container are alternately disposed, and a plurality of slots extending in a circumferential direction of the processing container is formed at a connection portion of the resonator and the downstream waveguide.
(7) The plasma processing apparatus of (6), wherein the downstream waveguide includes an annular space, and
wherein the plurality of slots is connected to the annular space.
(8) The plasma processing apparatus of (6) or (7), wherein the elastic member includes an elastic member provided on an inner circumferential side of the plurality of slots and an elastic member provided on an outer circumferential side of the plurality of slots.
(9) The plasma processing apparatus of any one of (1) to (8), further including a shower plate configured to supply a process gas to the processing space,
wherein the emitter is formed of an annular dielectric and is provided to surround the shower plate.
(10) A plasma processing method for a plasma processing apparatus,
wherein the plasma processing apparatus includes:
a processing container configured to provide a processing space;
an emitter configured to emit electromagnetic waves into the processing space;
a waveguide configured to supply the electromagnetic waves to the emitter, and including an upstream waveguide constituting a portion of the waveguide and a downstream waveguide constituting another portion of the waveguide, the downstream waveguide being connected to the upstream waveguide via an elastic member; and
a plurality of actuators configured to adjust a pressing force at a connection surface between the upstream waveguide and the downstream waveguide to adjust a gap length between the upstream waveguide and the downstream waveguide,
wherein the plasma processing method includes controlling the plurality of actuators to vary the gap length along a circumferential direction of the processing container when a substrate as a processing target is plasma-processed in the processing space.

According to the present disclosure in some embodiments, it is possible to control a distribution of plasma in a circumferential direction.

While certain embodiments have been described, these embodiments have been presented by way of example only, and are not intended to limit the scope of the disclosure. Indeed, the embodiments described herein may be embodied in a variety of other forms. Furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A plasma processing apparatus, comprising:
a processing container configured to provide a processing space;
an emitter configured to emit electromagnetic waves to the processing space; and
a waveguide configured to supply the electromagnetic waves to the emitter,
wherein the waveguide includes an upstream waveguide constituting a portion of the waveguide and a downstream waveguide constituting another portion of the waveguide, the downstream waveguide being connected to the upstream waveguide via an elastic member, and
wherein a gap length of a gap between the upstream waveguide and the downstream waveguide is adjustable by a pressing force between the upstream waveguide and the downstream waveguide.

2. The plasma processing apparatus of claim 1, wherein the elastic member is a coil spring.

3. The plasma processing apparatus of claim 2, further comprising a plurality of actuators configured to adjust the pressing force at a contact surface between the upstream waveguide and the downstream waveguide.

4. The plasma processing apparatus of claim 3, further comprising an electric field sensor provided in the emitter and configured to detect an electric field,
wherein the gap length is adjusted based on the detected electric field.

5. The plasma processing apparatus of claim 4, further comprising a controller,
wherein the controller is configured to control the plasma processing apparatus to execute controlling the plurality of actuators to vary the gap length along a circumferential direction of the processing container when a substrate as a processing target is plasma-processed in the processing space.

6. The plasma processing apparatus of claim 1, further comprising a plurality of actuators configured to adjust the pressing force at a contact surface between the upstream waveguide and the downstream waveguide.

7. The plasma processing apparatus of claim 1, wherein the upstream waveguide includes a resonator resonating with the electromagnetic waves, and
wherein the resonator is configured such that a disk connected to a conductor on a central axis side of the processing container and a disk connected to a conductor on an outer wall side of the processing container are alternately disposed, and a plurality of slots extending in a circumferential direction of the processing container is formed at a connection portion of the resonator and the downstream waveguide.

8. The plasma processing apparatus of claim 7, wherein the downstream waveguide includes an annular space, and
wherein the plurality of slots is connected to the annular space.

9. The plasma processing apparatus of claim 7, wherein the elastic member includes an elastic member provided on an inner circumferential side of the plurality of slots and an elastic member provided on an outer circumferential side of the plurality of slots.

10. The plasma processing apparatus of claim 1, further comprising a shower plate configured to supply a process gas to the processing space,
wherein the emitter is formed of an annular dielectric and is provided to surround the shower plate.

11. A plasma processing method for use in a plasma processing apparatus,
wherein the plasma processing apparatus comprises:
a processing container configured to provide a processing space;
an emitter configured to emit electromagnetic waves to the processing space;
a waveguide configured to supply the electromagnetic waves to the emitter, and including an upstream waveguide constituting a portion of the waveguide and a downstream waveguide constituting another portion of the waveguide, the downstream waveguide being connected to the upstream waveguide via an elastic member; and
a plurality of actuators configured to adjust a pressing force at a connection surface between the upstream waveguide and the downstream waveguide to adjust a gap length of a gap between the upstream waveguide and the downstream waveguide,
wherein the plasma processing method comprises controlling the plurality of actuators to vary the gap length along a circumferential direction of the processing container when a substrate as a processing target is plasma-processed in the processing space.
